(19) United States
(12) Patent Application Publication
(10) Pub. No.: US 2026/0180283 A1
(43) Pub. Date: Jun. 25, 2026

(54) DRIVING CIRCUIT AND VERTICAL CAVITY SURFACE EMITTING LASER SYSTEM

(71) Applicant: LUXIC Technology (Guangzhou) Co., Ltd, Guangzhou (CN)

(72) Inventors: Dong CHEN, Guangzhou (CN); Fan MENG, Guangzhou (CN)

(73) Assignee: LUXIC Technology (Guangzhou) Co., Ltd, Guangzhou (CN)

(21) Appl. No.: 19/430,332

(22) Filed: Dec. 23, 2025

(30) Foreign Application Priority Data
Dec. 24, 2024 (CN) 2024119190444

(51) Int. Cl. H01S 5/042; H01S 5/183; H03F 3/45

(52) U.S. Cl. CPC H01S 5/042; H01S 5/183; H03F 3/45475

(57) ABSTRACT

This disclosure provides a driving circuit. An output end of a bias current control sub-circuit is connected to an output end of an output driving sub-circuit and a driven element; the output driving sub-circuit includes a differential pair module circuit; a drain of PMOS transistor is connected to a load resistor RL1 and a load resistor RL2; one end of the load resistor RL2 close to the driven element is the output end of the output driving sub-circuit, and one end of the load resistor Rf is connected to a first input end of a first operational amplifier; one end of the load resistor Rref is connected to a second input end of the first operational amplifier; and an output end of the first operational amplifier is connected to a gate of the PMOS transistor. This disclosure provides an optimized driving circuit, which can achieve higher-speed optical communication applications.

### CROSS-REFERENCE TO RELATED APPLICATIONS

The application claims priority to Chinese patent application No. 2024119190444, filed on Dec. 24, 2024, the entire contents of which are incorporated herein by reference.

### TECHNICAL FIELD

This disclosure relates to the technical field of circuits, and in particular, to a driving circuit and a vertical cavity surface emitting laser system.

### BACKGROUND

In modern optical communication systems, vertical cavity surface emitting laser (VCSEL) drivers are widely used due to their excellent performances, such as low power consumption, high bandwidth, small size, low cost, and ease of integration. Restricted by cost and element structure, VCSEL drivers usually employ direct current coupling to drive VCSEL lasers with common cathodes. The demand for VCSEL optical power varies in different application environments, resulting in significant differences in the required bias current of the driver. In high-speed communication, limited by the operating voltage and power consumption constraints of the driver, a bias current of 4˜8 mA is typically used. However, a larger operating current implies a higher operating voltage of the VCSEL, which leads to a smaller power supply voltage margin. Therefore, a bias circuit design is required. In existing solutions, a driving stage voltage is raised to ensure a voltage margin and circuit performance. However, a new power supply will be introduced, increasing circuit complexity and power consumption, and resulting in high impedance seen from an output node, which mismatches with the VCSEL and causes problems such as signal reflection, leading to degraded signal quality in high-speed applications. Furthermore, the current source needs to flow through a large current, which results in a large size of the transistor and generates a large parasitic capacitance, which in turn affects the high-frequency performance. Currently, there is a lack of simple and effective solutions to the above drawbacks.

### SUMMARY

An objective of this disclosure is to provide a driving circuit and a vertical cavity surface emitting laser system. Through the optimized design of a bias current control sub-circuit, a modulation current control sub-circuit, and an output driving sub-circuit, higher-speed optical communication applications are achieved.

To achieve the above objective, this disclosure provides a driving circuit, including a bias current control sub-circuit and an output driving sub-circuit. An input end of the bias current control sub-circuit is connected to a power supply, and an output end of the bias current control sub-circuit is connected to an output end of the output driving sub-circuit and a driven element; the output driving sub-circuit includes a differential pair module circuit, the differential pair module circuit includes a load resistor RL1 and a load resistor RL2, a PMOS transistor is disposed between a power supply of the differential pair module circuit and the load resistor RL1 and the load resistor RL2, a source of the PMOS transistor is connected to the power supply of the differential pair module circuit, and a drain of the PMOS transistor is connected to the load resistor RL1 and the load resistor RL2 to form an intersection point; one end of the load resistor RL2 close to the driven element is the output end of the output driving sub-circuit, one end of the load resistor RL2 close to the driven element is further connected to one end of a load resistor Rf, and one end of the load resistor Rf away from the load resistor RL2 is connected to a first input end of a first operational amplifier; one end of the load resistor RL1 close to the PMOS transistor is further connected to one end of a load resistor Rref, one end of the load resistor Rref away from the load resistor RL1 is connected to a second input end of the first operational amplifier, and one end of the load resistor Rref away from the load resistor RL1 is connected to a first current source; and an output end of the first operational amplifier is connected to a gate of the PMOS transistor.

Optional, the bias current control sub-circuit includes a current mirror module circuit.

Optional, the current mirror module circuit includes a cascade structure circuit.

Optional, the differential pair module circuit further includes a second current source, a transistor Q1, and a transistor Q2; one end of the second current source is grounded, and one end of the second current source away from a ground direction is connected to both an emitter of the transistor Q1 and an emitter of the transistor Q2; and a collector of the transistor Q1 is connected to one end of the load resistor RL1 away from the PMOS transistor, and a collector of the transistor Q2 is connected to one end of the load resistor RL2 away from the PMOS transistor.

Optional, a transistor Q3 is disposed between the transistor Q1 and the load resistor RL1, and a transistor Q4 is disposed between the transistor Q2 and the load resistor RL2; a collector of the transistor Q3 is connected to one end of the load resistor RL1 away from the PMOS transistor, and an emitter of the transistor Q3 is connected to the collector of the transistor Q1; and a collector of the transistor Q4 is connected to one end of the load resistor RL2 away from the PMOS transistor, and an emitter of the transistor Q4 is connected to the collector of the transistor Q2.

Optional, the driving circuit further includes a transistor Q5, a transistor Q6, and a third current source. One end of the third current source is grounded, and one end of the third current source away from a ground direction is connected to both an emitter of the transistor Q5 and an emitter of the transistor Q6; a collector of the transistor Q5 is connected to both one end of the load resistor RL1 away from the PMOS transistor and the collector of the transistor Q1; and a collector of the transistor Q6 is connected to both one end of the load resistor RL2 away from the PMOS transistor and the collector of the transistor Q2.

Optional, the first current source includes a second operational amplifier, a transistor QB1, and an emitter resistor RE2, and the second current source includes a third operational amplifier, a transistor QB2, and an emitter resistor RE3. One end of the emitter resistor RE2 is grounded, and one end of the emitter resistor RE2 away from a ground direction is connected to both an emitter of the transistor QB1 and a reverse input end of the second operational amplifier; one end of the emitter resistor RE3 is grounded, and one end of the emitter resistor RE3 away from a ground direction is connected to both an emitter of the transistor QB2 and a reverse input end of the third operational amplifier; a collector of the transistor QB1 is connected to one end of the load resistor Rref away from the load resistor RL1, and a base of the transistor QB1 is connected to an output end of the second operational amplifier; a collector of the transistor QB2 is connected to both the emitter of the transistor Q1 and the emitter of the transistor Q2, and a base of the transistor QB2 is connected to an output end of the third operational amplifier; and forward input ends of the second operational amplifier and the third operational amplifier are connected to a first temperature compensation current source.

Optional, the driving circuit further includes a transistor Q5, a transistor Q6, and a third current source. One end of the third current source is grounded, one end of the third current source away from a ground direction is connected to both an emitter of the transistor Q5 and an emitter of the transistor Q6; a collector of the transistor Q5 is connected to both one end of the load resistor RL1 away from the PMOS transistor and the collector of the transistor Q1; and a collector of the transistor Q6 is connected to both one end of the load resistor RL2 away from the PMOS transistor and the collector of the transistor Q2. The third current source includes a fourth operational amplifier, a transistor QB3, and an emitter resistor RE4; the first current source further includes a fifth operational amplifier, a transistor QB4, and an emitter resistor RE5; one end of the emitter resistor RE4 is grounded, and one end of the emitter resistor RE4 away from a ground direction is connected to both an emitter of the transistor QB3 and a reverse input end of the fourth operational amplifier; one end of the emitter resistor RE5 is grounded, and one end of the emitter resistor RE5 away from a ground direction is connected to both an emitter of the transistor QB4 and a reverse input end of the fifth operational amplifier; a collector of the transistor QB3 is connected to both the emitter of the transistor Q5 and the emitter of the transistor Q6, and a base of the transistor QB3 is connected to an output end of the fourth operational amplifier; a collector of the transistor QB4 is connected to one end of the load resistor Rref away from the load resistor RL1, and a base of the transistor QB4 is connected to an output end of the fifth operational amplifier; and forward input ends of the fourth operational amplifier and the fifth operational amplifier are connected to a second temperature compensation current source.

Optional, the driving circuit further includes a plurality of inductors, where the inductors are configured to weaken a parasitic capacitance in the circuit.

This disclosure further provides a vertical cavity surface emitting laser system, including the driving circuit as described in any of the above, where the driven element is a vertical cavity surface emitting laser.

The vertical cavity surface emitting laser system provided by this disclosure has the following beneficial effects:

This disclosure provides a driving circuit, including a bias current control sub-circuit and an output driving sub-circuit. An input end of the bias current control sub-circuit is connected to a power supply, and an output end of the bias current control sub-circuit is connected to an output end of the output driving sub-circuit and a driven element; the output driving sub-circuit includes a differential pair module circuit, the differential pair module circuit includes a load resistor RL1 and a load resistor RL2, a PMOS transistor is disposed between a power supply of the differential pair module circuit and the load resistor RL1 and the load resistor RL2, a source of the PMOS transistor is connected to the power supply of the differential pair module circuit, and a drain of the PMOS transistor is connected to the load resistor RL1 and the load resistor RL2 to form an intersection point; one end of the load resistor RL2 close to the driven element is the output end of the output driving sub-circuit, one end of the load resistor RL2 close to the driven element is further connected to one end of a load resistor Rf, and one end of the load resistor Rf away from the load resistor RL2 is connected to a first input end of a first operational amplifier; one end of the load resistor RL1 close to the PMOS transistor is further connected to one end of a load resistor Rref, one end of the load resistor Rref away from the load resistor RL1 is connected to a second input end of the first operational amplifier, and one end of the load resistor Rref away from the load resistor RL1 is connected to a first current source; and an output end of the first operational amplifier is connected to a gate of the PMOS transistor. With such an arrangement, in this disclosure, the driving current is modulated by using both a resistive load and the bias current control sub-circuit. The advantages of this solution lie in that output impedance matching is effectively achieved through the resistive load, and the size of a current mirror load transistor of the bias current control sub-circuit can be reduced, thereby reducing a load of the driving stage, and facilitating an increase in circuit bandwidth and an achievement of superior gain-bandwidth performance. The modulation current control circuit implemented by a feedback loop composed of the operational amplifier cooperates with the output stage to form a current clamping circuit, ensuring the stability of the output DC current, so that a modulation current and a bias current are respectively adjustable, and it is ensured that the bias current does not flow into the output stage, causing the bias current to be inconsistent with expectations.

The vertical cavity surface emitting laser system includes the driving circuit as described in any of the above, where the driven element is a vertical cavity surface emitting laser. Since the vertical cavity surface emitting laser system includes the driving circuit, the vertical cavity surface emitting laser system modulates the driving current by using both the resistive load and the bias current control sub-circuit. The advantages of this solution lie in that output impedance matching is effectively achieved through the resistive load, so that the size of a current mirror load transistor of the bias current control sub-circuit can be reduced, thereby reducing a load of the driving stage, and facilitating an increase in circuit bandwidth and an achievement of superior gain-bandwidth performance. The modulation current control circuit implemented by a feedback loop composed of the operational amplifier cooperates with the output stage to form a current clamping circuit, ensuring the stability of the output DC current, so that a modulation current and a bias current are respectively adjustable, and it is ensured that the bias current does not flow into the output stage, causing the bias current to be inconsistent with expectations.

### BRIEF DESCRIPTION OF THE DRAWINGS

FIG. 1 is a schematic diagram of a circuit principle of a vertical cavity surface emitting laser driver according to an embodiment of the prior art;

FIG. 2 is a schematic diagram of a circuit principle of a driving circuit according to a first embodiment of this disclosure;

FIG. 3 is a schematic diagram of a circuit principle of a bias current control sub-circuit of a driving circuit according to a first embodiment of this disclosure;

FIG. 4 is a schematic diagram of a circuit principle of a bias current control sub-circuit of a driving circuit according to a second embodiment of this disclosure;

FIG. 5 is a schematic diagram of a circuit principle of an output driving sub-circuit of a driving circuit according to a first embodiment of this disclosure;

FIG. 6 is a schematic diagram of a circuit principle of an output driving sub-circuit of a driving circuit according to a second embodiment of this disclosure;

FIG. 7 is a schematic diagram of a circuit principle of an output driving sub-circuit of a driving circuit according to a third embodiment of this disclosure;

FIG. 8 is a schematic diagram of a circuit principle of a first current source and a second current source of a driving circuit according to an embodiment of this disclosure;

FIG. 9 is a schematic diagram of a circuit principle of a first current source, a second current source, and a third current source of a driving circuit according to an embodiment of this disclosure; and

FIG. 10 is a schematic diagram of a circuit principle of a driving circuit according to a second embodiment of this disclosure.

### REFERENCE NUMERALS IN THE DRAWINGS

01—bias current control sub-circuit; 011—bias current control sub-circuit current source;
02—output driving sub-circuit; 020—intersection point; 021—second current source;
03—modulation current control sub-circuit; 031—first current source;
10—driven element;
041—third current source;
051—compensation current source unit with temperature coefficient in first temperature compensation current source; 052—compensation current source unit without temperature coefficient in first temperature compensation current source;
061—compensation current source unit with temperature coefficient in second temperature compensation current source; 062—compensation current source unit without temperature coefficient in second temperature compensation current source;
100—inductor.

### DETAILED DESCRIPTION OF THE EMBODIMENTS

To make the objectives, advantages, and features of this disclosure clearer, this disclosure is described in further detail below with reference to the accompanying drawings and specific embodiments. It should be noted that the accompanying drawings are all in a very simplified form and are not drawn to scale, only for the purpose of conveniently and clearly assisting in explaining the embodiments of this disclosure. In addition, the structures shown in the accompanying drawings are often part of the actual structures. In particular, each accompanying drawing focuses on different aspects to be presented and may adopt different scales at times.

It should be understood that when an element or layer is referred to as being “on” or “connected to” other elements or layers, it can be directly on or connected to the other elements or layers, or may include intervening elements or layers. In contrast, when an element is referred to as being “directly on” or “directly connected to” other elements or layers, no intervening elements or layers are included. Although the terms “first”, “second”, “third”, etc. can be used to describe various elements, components, regions, layers, and/or sections, these elements, components, regions, layers, and/or sections should not be limited by these terms. These terms are only used to distinguish one element, component, region, layer, or section from another element, component, region, layer, or section. Therefore, a first element, component, region, layer, or section discussed below may be represented as a second element, component, region, layer, or section without departing from the teachings of this disclosure. Spatial relationship terms such as “under”, “below”, “lower”, “over”, “above”, “upper” and the like may be used herein for convenience of description to describe the relationship between an element or feature shown in the figures and other elements or features. It should be appreciated that in addition to orientations shown in the figures, the spatial relationship terms also encompass different orientations of devices in use and in operation. For example, if the devices in the figures are flipped, elements or features described as being “under”, “below,” or “lower” would then be oriented as being “above” the other elements or features. The devices may also be oriented in other ways (rotated 90 degrees or at other orientations), and the spatial description terms used herein should be interpreted accordingly. The terms used herein are for the purpose of describing specific embodiments only and are not intended as limitations of this disclosure. As used herein, the singular forms “a”, “an”, and “said/the” are also intended to include plural forms unless the context clearly indicates otherwise. It should also be understood that the term “comprise/include” is used to determine the inclusion of features, steps, operations, elements, and/or components, but does not preclude the inclusion or addition of one or more other features, steps, operations, elements, components, and/or groups. As used herein, the term “and/or” includes any and all combinations of the associated listed items.

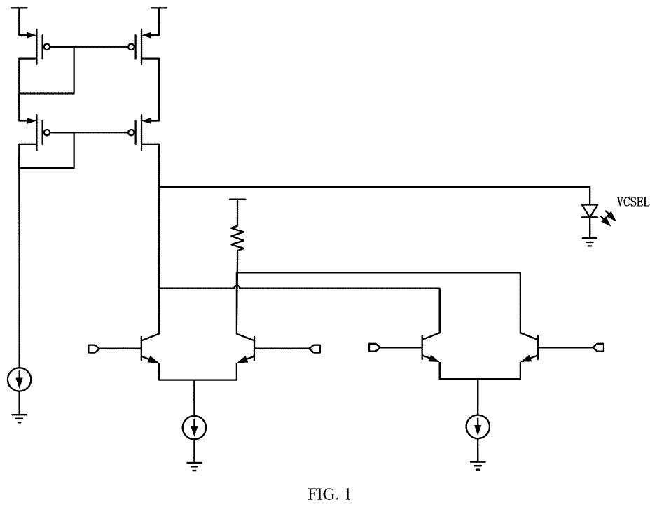

Referring to FIG. 1, FIG. 1 is a schematic diagram of a circuit principle of a vertical cavity surface emitting laser driver according to an embodiment of the prior art. In the prior art, a driving stage voltage is raised to ensure a voltage margin and circuit performance. However, a new power supply will be introduced, increasing circuit complexity and power consumption. For example, the solution in FIG. 1 uses a PMOS transistor current source as a DC bias load, resulting in high impedance seen from an output node, which mismatches with the VCSEL and causes problems such as signal reflection, leading to degraded signal quality in high-speed applications. Furthermore, the current source needs to flow through a large current, which results in a large size of the transistor and generates a large parasitic capacitance, which in turn affects the high-frequency performance.

An objective of this disclosure is to provide a driving circuit and a vertical cavity surface emitting laser system. Through the optimized design of a bias current control sub-circuit, a modulation current control sub-circuit, and an output driving sub-circuit, higher-speed optical communication applications are achieved.

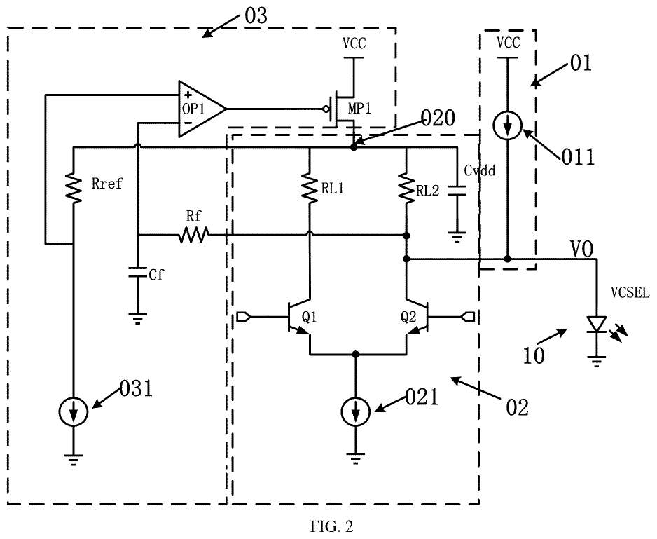

Referring to FIG. 2, FIG. 2 is a schematic diagram of a circuit principle of a driving circuit according to a first embodiment of this disclosure. As shown in FIG. 2, to achieve the above purpose, this disclosure provides a driving circuit, including a bias current control sub-circuit 01 and an output driving sub-circuit 02, where
an input end of the bias current control sub-circuit 01 is connected to a power supply VCC, and an output end of the bias current control sub-circuit 01 is connected to an output end of the output driving sub-circuit 02 and a driven element 10;
the output driving sub-circuit 02 includes a differential pair module circuit, and the differential pair module circuit includes a load resistor RL1 and a load resistor RL2; a PMOS transistor MP1 is disposed between a power supply of the differential pair module circuit and the load resistor RL1 and the load resistor RL2; and a source of the PMOS transistor MP1 is connected to the power supply of the differential pair module circuit, and a drain of the PMOS transistor MP1 is connected to the load resistor RL1 and the load resistor RL2 to form an intersection point 020;
one end of the load resistor RL2 close to the driven element 10 is the output end of the output driving sub-circuit 02, one end of the load resistor RL2 close to the driven element 10 is further connected to one end of a load resistor Rf, and one end of the load resistor Rf away from the load resistor RL2 is connected to a first input end of a first operational amplifier OP1 (in the embodiment shown in FIG. 2, the first input end is a reverse input end);
one end of the load resistor RL1 close to the PMOS transistor MP1 is further connected to one end of a load resistor Rref, one end of the load resistor Rref away from the load resistor RL1 is connected to a second input end of the first operational amplifier OP1 (in the embodiment shown in FIG. 2, the second input end is a forward input end), and one end of the load resistor Rref away from the load resistor RL1 is connected to a first current source 031; and
an output end of the first operational amplifier OP1 is connected to a gate of the PMOS transistor MP1.

It should be understood that the driving circuit shall further include a capacitor Cf and a capacitor Cvdd. One end of the capacitor Cf is grounded, and one end of the capacitor Cf away from a ground direction is connected to the first input end of the first operational amplifier OP1 (in the embodiment shown in FIG. 2, the first input end is the reverse input end) and to one end of the load resistor Rf away from the load resistor RL2. One end of the capacitor Cvdd is grounded, and one end of the capacitor Cvdd away from a ground direction is connected to: one end of the load resistor RL2 close to the drain of the PMOS transistor MP1, one end of the load resistor RL1 close to the drain of the PMOS transistor MP1, the drain of the PMOS transistor MP1, and one end of the load resistor Rref away from the first current source 031.

With such an arrangement, in this disclosure, the driving current is modulated by using both a resistive load and the bias current control sub-circuit 01. The advantages of this solution lie in that output impedance matching is effectively achieved through the resistive load, and the size of a current mirror load transistor of the bias current control sub-circuit can be reduced, thereby reducing a load of the driving stage, and facilitating an increase in circuit bandwidth and an achievement of superior gain-bandwidth performance. The modulation current control sub-circuit 03 implemented by a feedback loop composed of the operational amplifier cooperates with the output stage to form a current clamping circuit, ensuring the stability of the output DC current, so that a modulation current and a bias current are respectively adjustable, and it is ensured that the bias current does not flow into the output stage, causing the bias current to be inconsistent with expectations. Specifically, a proportional relationship can be set between the load resistor Rref and the load resistor RL2, enabling the voltages applied to the forward input end and the reverse input end of the first operational amplifier OP1 to be consistent, so that the first operational amplifier OP1 is configured to output a required target value level. This scheme requires that the signals at both ends of the operational amplifier are low-frequency signals. Therefore, it is necessary to extract the DC voltage of the output node through a relatively large RC filtering. The resistor common-mode end, serving as the power supply end of the driving stage, requires a large capacitor to ensure that the node is an ideal high-frequency signal ground. When a chip power supply voltage is limited, the PMOS is used as a voltage-regulating power transistor, so that the node is a high-impedance node. Therefore, attention should be paid to a zero-pole position of a loop during design to maintain loop stability. Further, the first operational amplifier OP1 is used to control the PMOS transistor MP1, ultimately achieving the acquisition of the required target voltage at the intersection point 020. It is achieved that the bias current does not flow into the output stage, causing the bias current to be inconsistent with expectations, thereby reducing the requirement of the bias circuit. The current mirror composed of the PMOS in the bias circuit can be reduced to approximately half its original size, which equivalently reduces the parasitic capacitance by half, effectively expanding the bandwidth while maintaining equal currents in the two branches of the differential pair module circuit.

For example, the driven element 10 is a VCSEL, with the load resistors set as RL1=RL2=RL and the reference load resistor set as Rref=RL*K. The DC value vfb of the VCSEL anode voltage VO is taken through Rf and Cf, where vfb=VO. The voltage at the intersection point 020 is set to be RVDD, the current of the first current source 031 is set to be Imod_ref, and the current of the second current source 021 is set to be Imod_tail, where Imod_tail=2K*Imod_ref. The bias current control sub-circuit current source 011 is set to be Ibias, and in static operating point analysis, it can be found that the voltage vref applied to the load resistor Rref=RVDD−Rref*Imod_ref, vfb=RVDD−RL2*I_{RL2}. The first operational amplifier OP1 is clamped, so that vref=vfb, and I_{RL2}=K*imod_ref can be achieved. Since the equivalent output resistance of Q2 is much greater than the internal resistance of the VCSEL, the Ibias current mainly flows into the VCSEL. Therefore, the Q2 collector end current IC_{Q2}=Ibias+I_{RL1}−Ibias _{VCSEL}≈I_{RL2}=K*imod_ref. Under the condition that the base currents of Q1 and Q2 are much less than the collector current, IC_{Q1}≈Imod_tail−IC_{Q2}=IC_{Q2}. Therefore, it can be ensured that the output stage is in a current balance state, thereby ensuring that the amplification gains for the high and low voltages of an input signal are basically consistent, and further maintaining the performance of rising and falling edges of an output eye diagram. The RVDD voltage is determined by the set operating current value, with RVDD=VO+V_{RL2}=VCC−VDS_{MP1}, where VCC is a power supply voltage. Therefore, a sufficient VCC voltage is required to ensure that the MP1 transistor operates normally under all operating scenarios. The Cvdd needs to be connected to the intersection point 020 to ensure that this point is an ideal differential-mode signal ground node capable of absorbing a high-frequency jitter signal. For a VCSEL with an equivalent internal resistance of Rv, this structure can achieve a VCSEL modulation current amplitude IMOD=RL/(RL+Rv)*Imod_tail =2*K*RL/(RL+Rv)*Imod_ref. It can be inferred therefrom that the IMOD is independent of the bias current control sub-circuit current source 011. The adjustability of the IMOD can be achieved by adjusting imod_ref through a digital configuration.

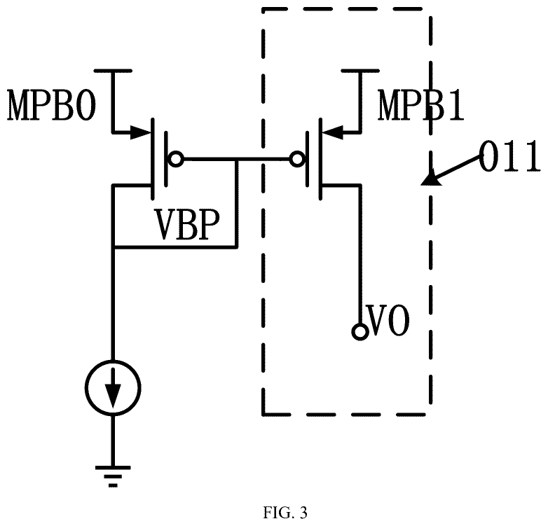

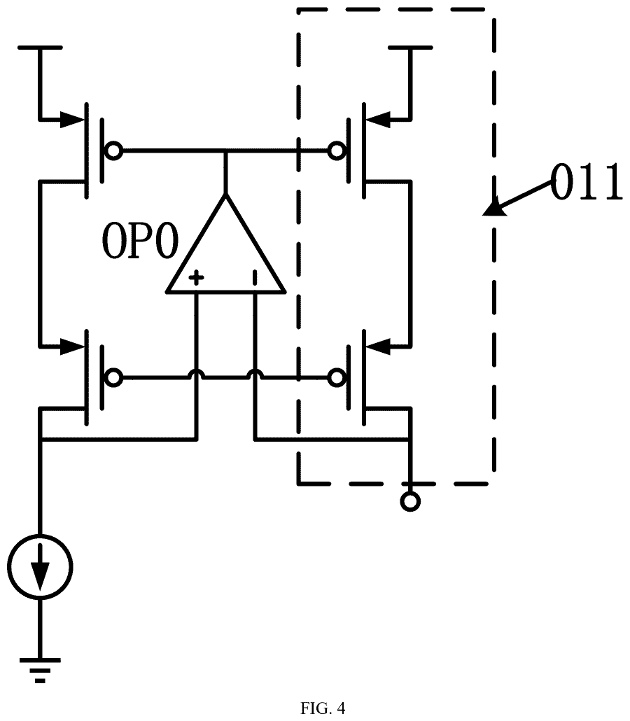

Specifically, referring to FIG. 3, FIG. 3 is a schematic diagram of a circuit principle of a bias current control sub-circuit of a driving circuit according to a first embodiment of this disclosure. As shown in FIG. 3, the bias current control sub-circuit 01 includes a current mirror module circuit. Further, referring to FIG. 4, FIG. 4 is a schematic diagram of a circuit principle of a bias current control sub-circuit of a driving circuit according to a second embodiment of this disclosure. As shown in FIG. 4, the difference between the bias current control sub-circuit of the driving circuit provided in the second embodiment and the bias current control sub-circuit of the driving circuit provided in the first embodiment lies in that the current mirror module circuit includes a cascade structure circuit. Both the current mirror module circuit and the cascade structure circuit can be disposed reference to the prior art, and will not be repeated herein.

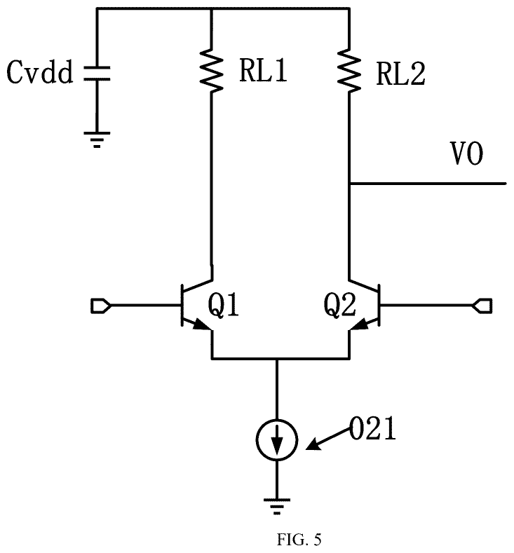

Further, referring to FIG. 5, FIG. 5 is a schematic diagram of a circuit principle of an output driving sub-circuit of a driving circuit according to a first embodiment of this disclosure. As shown in FIG. 5, the differential pair module circuit further includes a second current source 021, a transistor Q1, and a transistor Q2; one end of the second current source 021 is grounded, and one end of the second current source 021 away from a ground direction is connected to both an emitter of the transistor Q1 and an emitter of the transistor Q2; and a collector of the transistor Q1 is connected to one end of the load resistor RL1 away from the PMOS transistor MP1, and a collector of the transistor Q2 is connected to one end of the load resistor RL2 away from the PMOS transistor MP1. With such an arrangement, the differential pair module circuit essentially forms a CML (Current Mode Logic) structure, which has better gain-bandwidth performance and facilitates the control of output load matching.

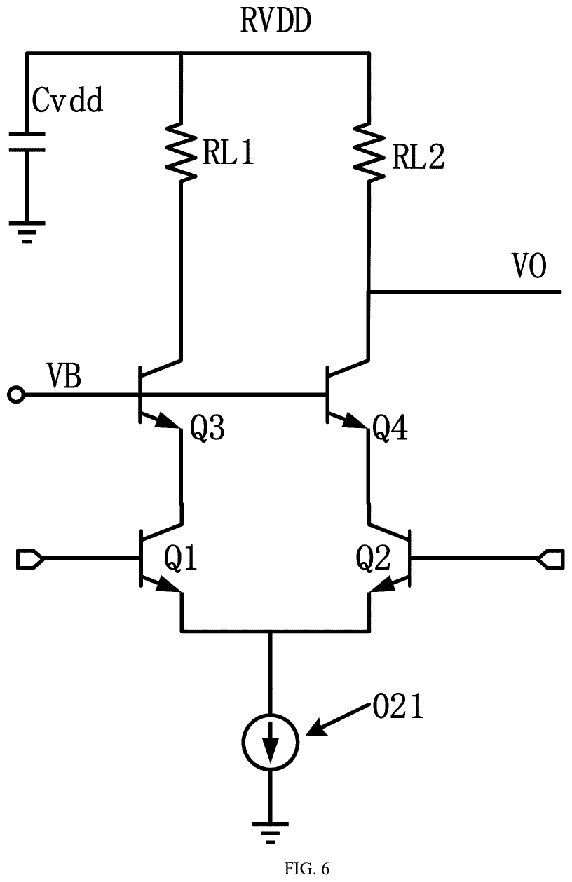

There are various optimization solutions for the CML structure. For example, referring to FIG. 6, FIG. 6 is a schematic diagram of a circuit principle of an output driving sub-circuit of a driving circuit according to a second embodiment of this disclosure. As shown in FIG. 6, the difference between the output driving sub-circuit of the driving circuit provided in the second embodiment and the output driving sub-circuit of the driving circuit provided in the first embodiment lies in that a transistor Q3 is disposed between the transistor Q1 and the load resistor RL1, and a transistor Q4 is disposed between the transistor Q2 and the load resistor RL2; a collector of the transistor Q3 is connected to one end of the load resistor RL1 away from the PMOS transistor, and an emitter of the transistor Q3 is connected to the collector of the transistor Q1; and a collector of the transistor Q4 is connected to one end of the load resistor RL2 away from the PMOS transistor MP1, and an emitter of the transistor Q4 is connected to the collector of the transistor Q2. With such an arrangement, a cascade stage is essentially added to the CML structure, offering advantages such as higher output impedance and output isolation.

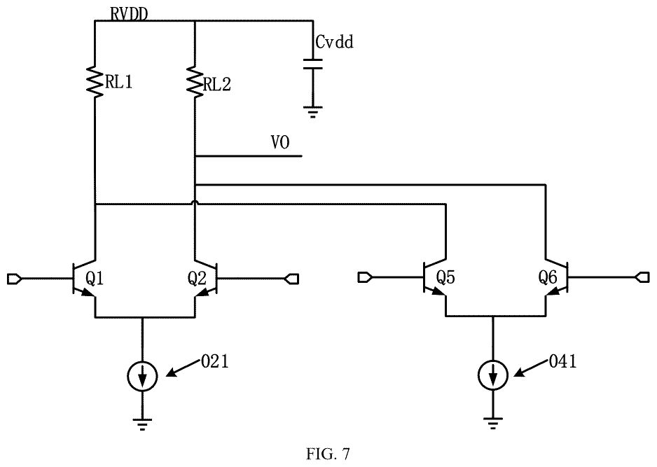

Further, referring to FIG. 7, FIG. 7 is a schematic diagram of a circuit principle of an output driving sub-circuit of a driving circuit according to a third embodiment of this disclosure. As shown in FIG. 7, the difference between the output driving sub-circuit of the driving circuit provided in the third embodiment and the output driving sub-circuit of the driving circuit provided in the second and the first embodiments lies in that the driving circuit further includes a transistor Q5, a transistor Q6, and a third current source. One end of the third current source is grounded, and one end of the third current source away from a ground direction is connected to both an emitter of the transistor Q5 and an emitter of the transistor Q6; a collector of the transistor Q5 is connected to both one end of the load resistor RL1 away from the PMOS transistor MP1 and the collector of the transistor Q1; and a collector of the transistor Q6 is connected to both one end of the load resistor RL2 away from the PMOS transistor and the collector of the transistor Q2. With such an arrangement, an FFE structure is essentially constituted. A stronger equalization function can be achieved by adjusting the polarity, delay, and amplitude of a second path signal, bandwidth expansion can be achieved, and characteristics such as the non-linearity of driven elements (e.g., VCSEL) can be compensated, thereby ensuring the performance of the VCSEL output signal.

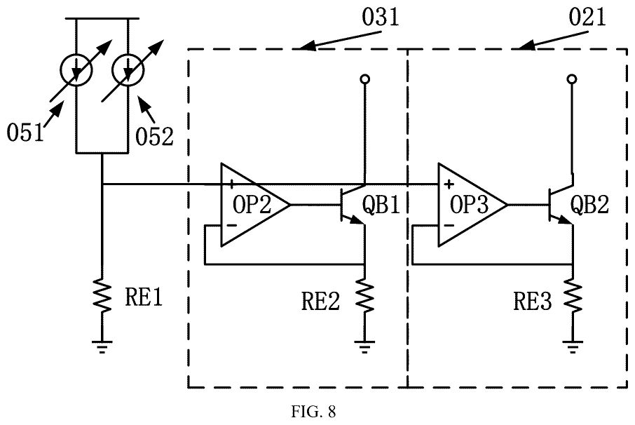

Further, referring to FIG. 8, FIG. 8 is a schematic diagram of a circuit principle of a first current source and a second current source of a driving circuit according to an embodiment of this disclosure. As shown in FIG. 8, the first current source includes a second operational amplifier OP2, a transistor QB1, and an emitter resistor RE2, and the second current source includes a third operational amplifier OP3, a transistor QB2, and an emitter resistor RE3. One end of the emitter resistor RE2 is grounded, and one end of the emitter resistor RE2 away from a ground direction is connected to both an emitter of the transistor QB1 and a reverse input end of the second operational amplifier OP2; one end of the emitter resistor RE3 is grounded, and one end of the emitter resistor RE3 away from a ground direction is connected to both an emitter of the transistor QB2 and a reverse input end of the third operational amplifier; a collector of the transistor QB1 is connected to one end of the load resistor Rref away from the load resistor RL1, and a base of the transistor QB1 is connected to an output end of the second operational amplifier OP2; a collector of the transistor QB2 is connected to both the emitter of the transistor Q1 and the emitter of the transistor Q2, and a base of the transistor QB2 is connected to an output end of the third operational amplifier OP3; and forward input ends of the second operational amplifier and the third operational amplifier OP3 are connected to a first temperature compensation current source. The first temperature compensation current source includes a compensation current source unit with temperature coefficient 051 and a compensation current source unit without temperature coefficient 052. Temperature compensation for the entire circuit can be achieved by configuring the two units. The current proportional relationship between the first current source and the second current source can be achieved by configuring the resistance values of the emitter resistors RE1, RE2, and RE3, thereby serving the first operational amplifier OP1.

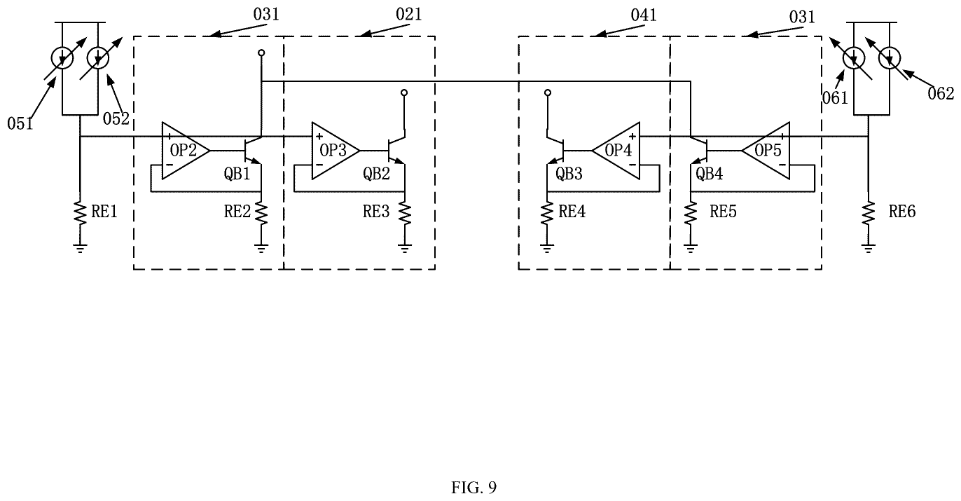

Further, referring to FIG. 9, FIG. 9 is a schematic diagram of a circuit principle of a first current source, a second current source, and a third current source of a driving circuit according to an embodiment of this disclosure. As shown in FIG. 9, the driving circuit further includes a transistor Q5, a transistor Q6, and a third current source. One end of the third current source is grounded, one end of the third current source away from a ground direction is connected to both an emitter of the transistor Q5 and an emitter of the transistor Q6; a collector of the transistor Q5 is connected to both one end of the load resistor RL1 away from the PMOS transistor and the collector of the transistor Q1; and a collector of the transistor Q6 is connected to both one end of the load resistor RL2 away from the PMOS transistor and the collector of the transistor Q2. The third current source includes a fourth operational amplifier, a transistor QB3, and an emitter resistor RE4; the first current source further includes a fifth operational amplifier, a transistor QB4, and an emitter resistor RE5; one end of the emitter resistor RE4 is grounded, and one end of the emitter resistor RE4 away from a ground direction is connected to both an emitter of the transistor QB3 and a reverse input end of the fourth operational amplifier; one end of the emitter resistor RE5 is grounded, and one end of the emitter resistor RE5 away from a ground direction is connected to both an emitter of the transistor QB4 and a reverse input end of the fifth operational amplifier; a collector of the transistor QB3 is connected to both the emitter of the transistor Q5 and the emitter of the transistor Q6, and a base of the transistor QB3 is connected to an output end of the fourth operational amplifier; a collector of the transistor QB4 is connected to one end of the load resistor Rref away from the load resistor RL1, and a base of the transistor QB4 is connected to an output end of the fifth operational amplifier; and forward input ends of the fourth operational amplifier and the fifth operational amplifier are connected to a second temperature compensation current source. The second temperature compensation current source includes a compensation current source unit with temperature coefficient 061 and a compensation current source unit without temperature coefficient 062. Temperature compensation for the entire circuit can be achieved by configuring the two units. The embodiment shown in FIG. 9 is particularly suitable for adapting to a CML structure with an FFE structure, essentially increasing a posttap tail current proportionally.

The implementation principle of temperature compensation is Ibias=k1*(α*Iptat1+(1−α)*Iflat1), Imod_ref=k2*(α*Iptat2+(1−α)*Iflat2), where Iptat is a current which is positively correlated with temperature, and Iflat is a temperature independent current. α is the proportion of the positive temperature coefficient current in the reference current. The magnitudes of α, k1, and k2 are controlled by a digital register, so that stable light emission of the VCSEL at different temperatures can be achieved.

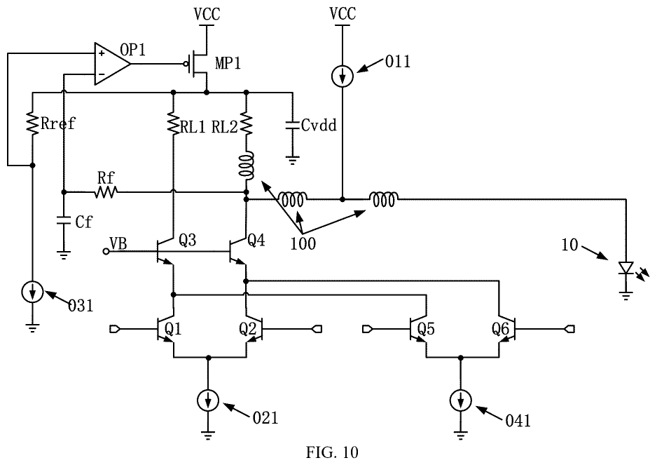

Further, referring to FIG. 10, FIG. 10 is a schematic diagram of a circuit principle of a driving circuit according to a second embodiment of this disclosure. As shown in FIG. 10, the driving circuit further includes a plurality of inductors 100, where the inductors 100 are configured to weaken a parasitic capacitance in the circuit. In the embodiment of the second driving circuit shown in FIG. 10, the CML structure may include both a cascade structure and an FFE structure, which will not be repeated herein.

It should be noted that all the transistors in this disclosure may be NPN transistors or NMOS transistors.

This disclosure further provides a vertical cavity surface emitting laser system, including the driving circuit as described in any of the above, where the driven element 10 is a vertical cavity surface emitting laser. Since the vertical cavity surface emitting laser system includes the driving circuit, the vertical cavity surface emitting laser system modulates the driving current by using both the resistive load and the bias current control sub-circuit. The advantages of this solution lie in that output impedance matching is effectively achieved through the resistive load, so that the size of a current mirror load transistor of the bias current control sub-circuit can be reduced, thereby reducing a load of the driving stage, and facilitating an increase in circuit bandwidth and an achievement of superior gain-bandwidth performance. The modulation current control circuit implemented by a feedback loop composed of the operational amplifier cooperates with the output stage to form a current clamping circuit, ensuring the stability of the output DC current, so that a modulation current and a bias current are respectively adjustable, making the bias current appear as a high-impedance environment when viewed in reverse from the output end of the output driving sub-circuit. It is ensured that the bias current does not flow into the output stage, causing the bias current to be inconsistent with expectations.

It should further be noted that although this disclosure has been disclosed above in preferred embodiments, the foregoing embodiments are not intended to limit this disclosure. For any person skilled in the art, without departing from the scope of the technical solutions of this disclosure, many possible changes and modifications may be made to the technical solutions of this disclosure by utilizing the technical contents disclosed above, or equivalent embodiments with equivalent changes may be modified. Therefore, any simple amendments, and equivalent changes and modifications made to the above embodiments based on the technical substance of this disclosure, without departing from the content of the technical solutions of this disclosure, shall fall within the protection scope of the technical solutions of this disclosure.

It should also be understood that, unless specifically stated or indicated otherwise, the terms “first”, “second”, “third”, etc., in the specification are only used to distinguish various components, elements, steps, etc., in the specification, and are not intended to indicate the logical relationship, sequential relationship, or the like between the various components, elements, steps, etc.

In addition, it should be recognized that the terms described herein are only used to describe specific embodiments and are not intended to limit the scope of this disclosure. It must be noted that the singular forms “a”, “an”, and “the” used herein and in the appended claims include plural references unless the context clearly dictates otherwise. For example, a reference to “a step” or “a device” means a reference to one or more steps or devices, and may include a secondary step as well as a secondary device. All conjunctions used should be understood in the broadest sense. Furthermore, the word “or” should be understood as having a definition of a logical “or” rather than a logical “exclusive-or”, unless the context clearly dictates otherwise. In addition, implementation of embodiments of this disclosure may include performing selected tasks manually, automatically, or in combination.

What is claimed is:

1. A driving circuit, comprising a bias current control sub-circuit and an output driving sub-circuit, wherein
an input end of the bias current control sub-circuit is connected to a power supply, and an output end of the bias current control sub-circuit is connected to an output end of the output driving sub-circuit and a driven element;
the output driving sub-circuit comprises a differential pair module circuit, and the differential pair module circuit comprises a load resistor RL1, a load resistor RL2, a second current source, a transistor Q1, and a transistor Q2; a PMOS transistor is disposed between a power supply of the differential pair module circuit and the load resistor RL1 and the load resistor RL2; a source of the PMOS transistor is connected to the power supply of the differential pair module circuit, and a drain of the PMOS transistor is connected to the load resistor RL1 and the load resistor RL2 to form an intersection point; one end of the second current source is grounded, and one end of the second current source away from a ground direction is connected to both an emitter of the transistor Q1 and an emitter of the transistor Q2; and a collector of the transistor Q1 is connected to one end of the load resistor RL1 away from the PMOS transistor, and a collector of the transistor Q2 is connected to one end of the load resistor RL2 away from the PMOS transistor;
a transistor Q3 is disposed between the transistor Q1 and the load resistor RL1, and a transistor Q4 is disposed between the transistor Q2 and the load resistor RL2; a collector of the transistor Q3 is connected to one end of the load resistor RL1 away from the PMOS transistor, an emitter of the transistor Q3 is connected to the collector of the transistor Q1, and a base of the transistor Q3 is connected to a voltage VB; and a collector of the transistor Q4 is connected to one end of the load resistor RL2 away from the PMOS transistor, an emitter of the transistor Q4 is connected to the collector of the transistor Q2, and a base of the transistor Q4 is connected to the voltage VB;
one end of the load resistor RL2 close to the driven element is the output end of the output driving sub-circuit, one end of the load resistor RL2 close to the driven element is further connected to one end of a load resistor Rf, and one end of the load resistor Rf away from the load resistor RL2 is connected to a first input end of a first operational amplifier;
one end of the load resistor RL1 close to the PMOS transistor is further connected to one end of a load resistor Rref, one end of the load resistor Rref away from the load resistor RL1 is connected to a second input end of the first operational amplifier, and one end of the load resistor Rref away from the load resistor RL1 is connected to a first current source; and
an output end of the first operational amplifier is connected to a gate of the PMOS transistor.

2. The driving circuit according to claim 1, wherein the bias current control sub-circuit comprises a current mirror module circuit.

3. The driving circuit according to claim 2, wherein the current mirror module circuit comprises a cascade structure circuit.

4. The driving circuit according to claim 1, further comprising a transistor Q5, a transistor Q6, and a third current source, wherein
one end of the third current source is grounded, and one end of the third current source away from a ground direction is connected to both an emitter of the transistor Q5 and an emitter of the transistor Q6;
a collector of the transistor Q5 is connected to both one end of the load resistor RL1 away from the PMOS transistor and the collector of the transistor Q1; and
a collector of the transistor Q6 is connected to both one end of the load resistor RL2 away from the PMOS transistor and the collector of the transistor Q2.

5. The driving circuit according to claim 1, wherein the first current source comprises a second operational amplifier, a transistor QB1, and an emitter resistor RE2, and the second current source comprises a third operational amplifier, a transistor QB2, and an emitter resistor RE3;
one end of the emitter resistor RE2 is grounded, and one end of the emitter resistor RE2 away from a ground direction is connected to both an emitter of the transistor QB1 and a reverse input end of the second operational amplifier;
one end of the emitter resistor RE3 is grounded, and one end of the emitter resistor RE3 away from a ground direction is connected to both an emitter of the transistor QB2 and a reverse input end of the third operational amplifier;
a collector of the transistor QB1 is connected to one end of the load resistor Rref away from the load resistor RL1, and a base of the transistor QB1 is connected to an output end of the second operational amplifier;
a collector of the transistor QB2 is connected to both the emitter of the transistor Q1 and the emitter of the transistor Q2, and a base of the transistor QB2 is connected to an output end of the third operational amplifier; and
forward input ends of the second operational amplifier and the third operational amplifier are connected to a first temperature compensation current source.

6. The driving circuit according to claim 5, further comprising a transistor Q5, a transistor Q6, and a third current source, wherein
one end of the third current source is grounded, and one end of the third current source away from a ground direction is connected to both an emitter of the transistor Q5 and an emitter of the transistor Q6;
a collector of the transistor Q5 is connected to both one end of the load resistor RL1 away from the PMOS transistor and the collector of the transistor Q1;
a collector of the transistor Q6 is connected to both one end of the load resistor RL2 away from the PMOS transistor and the collector of the transistor Q2;
the third current source comprises a fourth operational amplifier, a transistor QB3, and an emitter resistor RE4, and
the first current source further comprises a fifth operational amplifier, a transistor QB4, and an emitter resistor RE5;
one end of the emitter resistor RE4 is grounded, and one end of the emitter resistor RE4 away from a ground direction is connected to both an emitter of the transistor QB3 and a reverse input end of the fourth operational amplifier;
one end of the emitter resistor RE5 is grounded, and one end of the emitter resistor RE5 away from a ground direction is connected to both an emitter of the transistor QB4 and a reverse input end of the fifth operational amplifier;
a collector of the transistor QB3 is connected to both the emitter of the transistor Q5 and the emitter of the transistor Q6, and a base of the transistor QB3 is connected to an output end of the fourth operational amplifier;
a collector of the transistor QB4 is connected to one end of the load resistor Rref away from the load resistor RL1, and a base of the transistor QB4 is connected to an output end of the fifth operational amplifier; and
forward input ends of the fourth operational amplifier and the fifth operational amplifier are connected to a second temperature compensation current source.

7. The driving circuit according to claim 1, further comprising a plurality of inductors, wherein the inductors are configured to weaken a parasitic capacitance in the circuit.

8. A vertical cavity surface emitting laser system, comprising the driving circuit according to claims 1, wherein the driven element is a vertical cavity surface emitting laser.
